(19) United States
(12) Patent Application Publication
(10) Pub. No.: US 2012/0139115 A1
(43) Pub. Date: Jun. 7, 2012

(54) Integrated Circuit Device

(75) Inventors: Ha-Young You, Seoul (KR); Ju-Seung Kang, Seoul (KR); Youn-Soo Lee, Suwon-si (KR)

(73) Assignee: SAMSUNG ELECTRONICS CO., LTD., Suwon-si (KR)

(21) Appl. No.: 13/305,329

(22) Filed: Nov. 28, 2011

(30) Foreign Application Priority Data
Dec. 3, 2010 (KR) 10-2010-0122966

(51) Int. Cl. H01L 27/06

(52) U.S. Cl. 257/751; 257/E27.011

(57) ABSTRACT

In an integrated circuit device and method of manufacturing the same, a conductive structure and a wiring structure are sequentially arranged on a substrate having a through hole. The conductive structure includes semiconductor chips and a contact structure. The wiring structure includes a metal line through which signals are transferred to the conductive structure. A penetration electrode is positioned in the through hole. The penetration electrode includes a conductive plug electrically connected to one of the conductive structure and the wiring structure, and a pair of a base layer and a gap interposed between the conductive plug and a sidewall of the through-hole, thereby enclosing the conductive plug. The base layer also includes a product of a solid reaction of reactants of which diffusion speeds are different. Accordingly, the dielectric characteristics of the penetration electrode are improved by using the gap as a dielectric gap.

### CROSS-REFERENCE TO RELATED APPLICATIONS

This application claims the benefit of Korean Patent Application No. 10-2010-0122966 filed on Dec. 3, 2010, in the Korean Intellectual Property Office, the disclosure of which is incorporated herein in its entirety by reference.

### BACKGROUND

1. Field

Some example embodiments relate to an integrated circuit device and a method of manufacturing the same, and more particularly, to an integrated circuit device having a penetration electrode and a method of manufacturing the same.

2. Description of the Related Art

In response to the relatively high performance of recent electronic instruments, e.g., computer systems, there has been a strong need for higher integration degree and performance in integrated circuit devices with higher operational speed. The integration degree of the integration circuit devices is usually accomplished at the stage of fabricating semiconductor chips for the integrated circuit device and at the stage of packaging the semiconductor chips into the integrated circuit device in which the semiconductor chips are mounted on a base substrate, e.g., a printed circuit board (PCB).

When fabricating the semiconductor chips, various elements of the semiconductor chips, e.g., transistors and capacitors, are stacked in a 3-dimensional manner and more semiconductor chips are formed on a wafer, to thereby increase the degree of integration of the semiconductor chip. When packing the semiconductor chips, various packing technology has been used so as to mount more semiconductor chips on a single base substrate, to thereby increase the volume of the semiconductor package. Particularly, because the increase of the integration degree of the semiconductor package at the package stage requires less time and cost than that of the semiconductor chips at the fabrication stage, intensive research has been conducted on increasing the integration degree of the semiconductor package so as to increase the integration degree of the integrated circuit devices.

In conventional integrated circuit devices, a plurality of semiconductor chips in a package is stacked vertically and each of the semiconductor chips is electrically connected to each other by assemblers. Thus, a package including the semiconductor chips functions as an electronic single device. A metal wiring and/or a combination of a wiring and a solder ball have been widely used as the assembler. Particularly, a penetration electrode has been intensively used for connecting the vertically stacked semiconductor chips. A through-hole is provided at each semiconductor chip and the penetration electrode is arranged in the through-hole. Thus, the vertically stacked semiconductor chips are electrically connected with one another through the penetration electrode.

Due to the relatively high degree of integration of the semiconductor chips as well as the semiconductor package, the transient phenomena, e.g., resistance-capacitance delay (RC delay) and the cross-talk between neighboring wirings, are likely to have an effect on the operation speed of the integrated circuit devices rather than chip-based characteristics, e.g., the switching speed of each transistors in the integrated circuit devices.

The penetration electrode may sufficiently increase the operation speed of the integration circuit devices as compared with the assembler of the wire bonding and the solder ball. However, the RC delay caused by parasitic capacitance between the neighboring penetration electrodes is gradually increased because the gap distance between the neighboring penetration electrodes is decreased due to the downsizing and high integration degree of the integration circuit devices. Particularly, when data signals may be communicated with the integrated circuit devices at a higher speed, there is a possibility of signal loss caused by the signal interferences between the neighboring penetration electrodes. That is, the operation speed of the integration circuit devices is actually decreased due to the RC delay of the penetration electrodes.

The RC delay of wiring structures in semiconductor chips has been usually improved in such a way that an insulation interlayer having a relatively low dielectric constant is interposed between a contact and a metal wiring in the wiring structure and the contact and the metal wiring comprise a low-resistive material. However, because the penetration electrode of the semiconductor package is merely an additional interconnection penetrating the wafer, the formation of the penetration electrode using the low-dielectric insulation interlayer and/or the low-resistive material causes higher packaging costs and accuracy.

### SUMMARY

Some example embodiments of the present inventive concepts provide an integrated circuit device in which the transient phenomena and the RC delay between the neighboring penetration electrodes is improved without changes in material properties of the penetration electrode. Other example embodiments of the present inventive concepts provide a method of manufacturing the above integrated circuit devices.

Accordingly, an improved integration circuit device having a penetration electrode is provided in which the parasitic capacitance and transient phenomena between the neighboring penetration electrodes may be reduced without any change in material properties of the penetration electrodes.

According to example embodiments, there is provided an integrated circuit device including a conductive structure positioned on a substrate having a through hole, the conductive structure including a plurality of semiconductor chips and at least one contact structure, a wiring structure positioned on the conductive structure, the wiring structure including a metal line through which signals are transferred to the conductive structure, and a penetration electrode positioned in the through hole. The penetration electrode includes a conductive plug configured to electrically connect to at least one of the conductive structure and the wiring structure, and a pair of a base layer and a gap interposed between the conductive plug and a sidewall of the through hole such that the pair of the base layer and the gap encloses the conductive plug. The base layer includes a product of a solid reaction of reactants having different diffusion speeds.

In example embodiments, the gap may be filled with one of an air and a vacuum such that the conductive plug is enclosed by a dielectric air gap. The base layer may include at least one material selecting from the group consisting of BeNi, BeCo, Co₃S₄, CoSe, CoTe, ZnS, PbS, CuS, AuPt, MoS₂, AlN, CdS, ZnAl₂O₄, Zn₂SiO₄, SrTiO₃, BaTiO₃ and combinations thereof.

In example embodiments, the penetration electrode may further include an insulation layer for electrically insulating the conductive plug from the conductive structure and the wiring structure, and a barrier layer enclosing the conductive plug. The base layer may be positioned on the insulation layer, and the gap may be interposed between the base layer and the barrier layer. The gap may be interposed between the insulation layer and the base layer, and the base layer is positioned on the barrier layer. The insulation layer, the barrier layer and the base layer may be sequentially formed on the sidewall of the through hole, and the gap may be interposed between the base layer and the conductive plug.

In example embodiments, the conductive plug may include at least one material selected from the group consisting of copper (Cu), nickel (Ni), tungsten (W) and combinations thereof. The penetration electrode may penetrate through the conductive structure in order to make contact with a lower surface of the metal line of the wiring structure. The penetration electrode may penetrate through the conductive structure and the wiring structure in order to make contact with an upper surface of the metal line of the wiring structure.

According to example embodiments, there is provided a method of manufacturing an integrated circuit device including forming a conductive structure on a substrate, forming a wiring structure on the conductive structure, and forming a penetration electrode in a through hole of the substrate. The conductive structure includes a plurality of semiconductor chips and at least a contact structure. The wiring structure has a metal line through which signals are transferred to the conductive structure. Forming the penetration electrode includes forming a conductive plug in the through hole, the conductive plug configured to electrically connect to at least one of the conductive structure and the wiring structure, and forming a pair of a base layer and a gap between the conductive plug and a sidewall of the through hole by a solid reaction of reactants having different diffusion speeds such that the pair of the base layer and the gap encloses the conductive plug.

In example embodiments, forming the penetration electrode may include forming a recess such that the substrate is partially exposed, sequentially forming first and second material patterns and the conductive plug on sidewalls and a bottom surface of the recess such that the conductive plug fills the recess and is enclosed by the first and second material patterns, forming a preliminary penetration electrode by polishing a rear surface of the substrate and reducing a thickness of the substrate such that the first and the second material patterns and the conductive plug are exposed through the substrate and simultaneously forming the base layer and the gap through the solid reaction between materials of the first and the second material patterns under heat, so that the base layer includes a product of the solid reaction of the first and second material patterns and the gap is generated by a difference of the diffusion speeds of the materials of the first and the second material patterns in the solid reaction.

In example embodiments, a re-directional structure may be formed on the substrate such that the re-directional structure makes contact with the penetration electrode on a rear surface of the substrate. A contact terminal may be formed that makes contact with the re-directional structure. External signals may be transferred to the contact terminal, and the heat for the solid reaction may be generated from at least one the forming the re-directional structure and the forming the contact terminal.

In example embodiments, the gap may be generated on a nano scale due to an atomic diffusion of the materials between the first and the second material patterns. Forming the first and the second material patterns and the conductive plug in the recess may further include forming an insulation pattern on the sidewalls and the bottom surface of the recess, and forming a barrier layer enclosing the conductive plug. The first and the second material patterns may be formed between the insulation pattern and the barrier layer, so that the base layer and the gap may be formed between the insulation pattern and the barrier layer.

In example embodiments, the first and the second material patterns may be formed between the barrier layer and the conductive plug, so that the base layer and the gap may be formed between the barrier layer and the conductive plug.

In example embodiments, forming the recess may include partially removing the conductive structure, the wiring structure and the substrate so that the recess is defined by the conductive structure, the wiring structure and the substrate. Forming the insulation pattern, the first and the second material patterns and the barrier layer may include forming an insulation layer, first and second material layers and a preliminary barrier layer on the wiring structure and on a sidewall and a bottom surface of the recess along a surface profile of the recess, and planarizing the insulation layer, the first and the second material layers and the preliminary barrier layer until an upper surface of the wiring structure is exposed, so that the insulation layer, the first and the second material layers and the preliminary barrier layer remain in the recess.

In example embodiments, forming the recess may include partially removing the conductive structure and the substrate before the forming the wiring structure so that the recess is defined by the conductive structure and the substrate. Fanning the insulation pattern, the first and the second material patterns and the barrier layer may include fowling an insulation layer, first and second material layers and a preliminary barrier layer on the conductive structure and on a sidewall and a bottom surface of the recess along a surface profile of the recess, and planarizing the insulation layer, the first and the second material layers and the preliminary barrier layer until an upper surface of the conductive structure is exposed, so that the insulation layer, the first and the second material layers and the preliminary barrier layer remain in the recess.

In example embodiments, the first and the second material patterns may include reactants of the solid reaction, and the base layer may include at least one material selected from the group consisting of BeNi, BeCo, Co₃S₄, CoSe, CoTe, ZnS, PbS, CuS, AuPt, MoS₂, AlN, CdS, ZnAl₂O₄, Zn₂SiO₄, SrTiO₃, BaTiO₃ and combinations thereof.

According to example embodiments, there is provided an integrated circuit device including a conductive structure positioned on a substrate having a through hole, a wiring structure positioned on the conductive structure, and a penetration electrode positioned in the through hole, the penetration electrode including a conductive plug configured to electrically connect to at least one of the conductive structure and the wiring structure, and a dielectric gap interposed between the conductive plug and a sidewall of the through hole such that the dielectric gap encloses the conductive plug.

In example embodiments, the conductive structure may include a plurality of semiconductor chips and at least one contact structure, and the wiring structure may include a metal line through which signals are transferred to the conductive structure. The penetration electrode may further include a base layer adjacent to the dielectric gap, an insulation layer configured to electrically insulate the conductive plug from the conductive structure and the wiring structure, and a barrier layer enclosing the conductive plug. The base layer including a product of a solid reaction of reactants having different diffusion speeds.

According to example embodiments, there is provided a method of manufacturing an integrated circuit device including forming a conductive structure on a substrate, forming a wiring structure on the conductive structure, and forming a penetration electrode in a through hole of the substrate. Forming the penetration electrode may include forming a conductive plug in the through hole, the conductive plug configured to electrically connect to at least one of the conductive structure and the wiring structure, and forming a dielectric gap between the conductive plug and a sidewall of the through hole by a solid reaction of reactants having different diffusion speeds such that the dielectric gap encloses the conductive plug.

In example embodiments, the conductive structure may include a plurality of semiconductor chips and at least one contact structure, and the wiring structure may include a metal line through which signals are transferred to the conductive structure. Forming the penetration electrode may further include forming a base layer adjacent to the dielectric gap, forming an insulation layer to electrically insulate the conductive plug from the conductive structure and the wiring structure, and forming a barrier layer enclosing the conductive plug.

According to example embodiments of the present inventive concepts, an additional dielectric member may be provided around the penetration electrode penetrating through the substrate and making contact with the conductive structure and/or the wiring structure, thereby improving dielectric characteristics of the penetration electrode of the integrated circuit device. Particularly, a gap may be formed around the conductive plug of the penetration electrode by the solid reaction of the reactants for a base layer and just merely filling up the gap with a dry air may provide the dielectric air gap around the conductive plug of the penetration electrode. Thus, the dielectric characteristics of the penetration electrode may be more easily improved.

Accordingly, when the gap distance between the neighboring penetration electrodes may be reduced due to the high integration degree of the integrated circuit device and the high stack density of the stack package, the signal interferences and the parasitic capacitance may be sufficiently prevented or inhibited. Thus, the integration circuit device and the stack package including a plurality of the integrated circuit devices may be stably operated with more reliability.

### BRIEF DESCRIPTION OF THE DRAWINGS

Example embodiments will be more clearly understood from the following detailed description taken in conjunction with the accompanying drawings.

FIG. 1 is a plan view illustrating an integrated circuit device in accordance with example embodiments of the present inventive concepts;

FIG. 2A is a cross-sectional view illustrating a penetration electrode of the integrated circuit device shown in FIG. 1;

FIG. 2B is a modification of the penetration electrode shown in FIG. 2A;

FIGS. 3A to 3G are cross-sectional views illustrating processing steps for a method of manufacturing the integrated circuit device 900 shown in FIGS. 1 and 2A in accordance with example embodiments of the present inventive concepts;

FIGS. 4A to 4F are cross-sectional views illustrating processing steps for a method of manufacturing the integrated circuit device 900 shown in FIGS. 1 and 2A in accordance with example embodiments of the present inventive concepts;

FIG. 5 is a cross-sectional view illustrating a stack package in which a plurality of the integrated circuit devices shown in FIGS. 1 and 2A is stacked in accordance with example embodiments of the present inventive concepts; and

FIG. 6 is a cross-sectional view illustrating a stack package in which a plurality of the integrated circuit devices shown in FIGS. 1 and 2A is stacked in accordance with example embodiments of the present inventive concepts.

### DETAILED DESCRIPTION OF EXAMPLE EMBODIMENTS

Various example embodiments will be described more fully hereinafter with reference to the accompanying drawings, in which some example embodiments are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all teens (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

Integrated Circuit Device

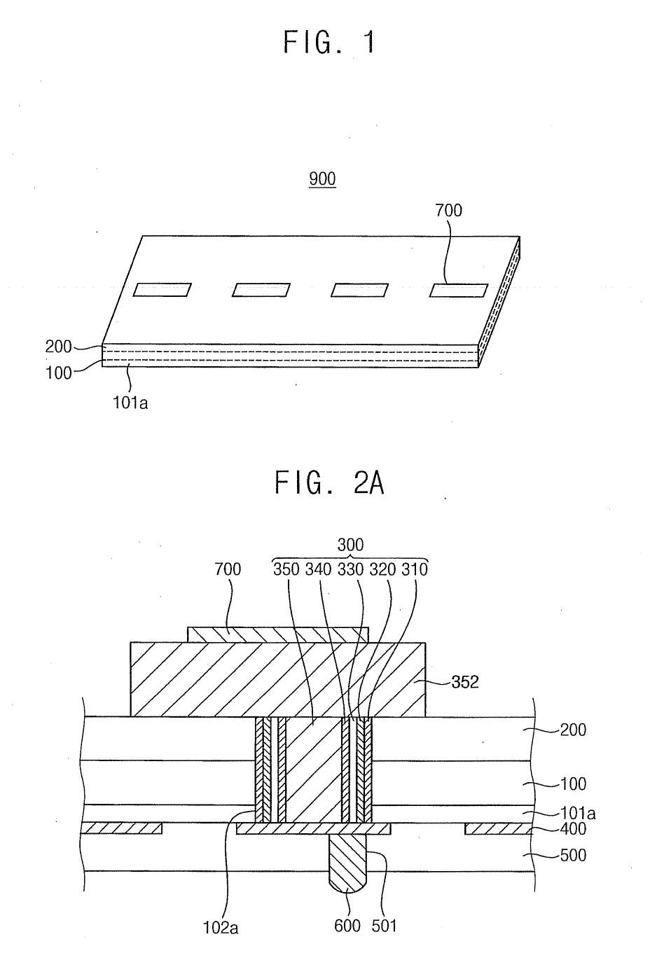

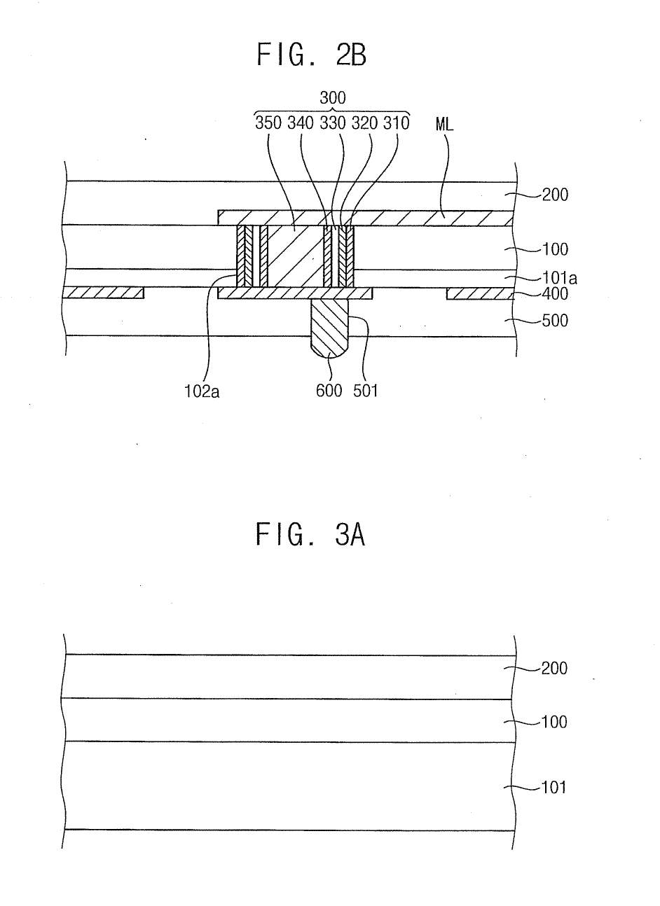

FIG. 1 is a plan view illustrating an integrated circuit device in accordance with example embodiments of the present inventive concepts. FIG. 2A is a cross-sectional view illustrating a penetration electrode of the integrated circuit device shown in FIG. 1 and FIG. 2B is a modification of the penetration electrode shown in FIG. 2A.

Referring to FIGS. 1, 2A and 2B, an integrated circuit device 900 in accordance with example embodiments of the present inventive concepts may include a conductive structure 100 having a plurality of semiconductor chips (not shown) and contact structures (not shown) stacked on a semiconductor substrate, e.g., a wafer, a wiring structure 200 electrically connected to the conductive structure through an insulation interlayer (not shown) and a penetration electrode 300 penetrating through the substrate and connecting with the conductive structure 100 and the wiring structure 200.

In example embodiments, the substrate 101a may include a cell area in which the semiconductor chips are arranged and electric data may be stored, and a peripheral area in which peripheral circuits may be arranged to thereby transfer the data signals to the conductive structures 100 through the wiring structure 200. Hereinafter, the surface of the substrate 101a on which the conductive structures 100 may be arranged may be referred to as front surface of the substrate and the surface opposite to the front surface may be referred to as rear surface of the substrate. In example embodiments, the rear surface of the substrate may be polished. Thus, the thickness of the substrate may be reduced to a predetermined or given degree. The reduction of the substrate thickness may facilitate the formation of a through-hole 102a of the substrate 101a.

The conductive structure 100 may include a plurality of semiconductor chips (not shown) that may be fabricated on the substrate 101a through a series of unit processes and a plurality of contact structures (not shown) making contact with the semiconductor chips. The semiconductor chips and the contact structures may be electrically insulated from each other by a lower insulation layer (not shown) and may be sequentially stacked on the substrate 101a.

Although not shown, the semiconductor chip may include a dynamic random access memory (DRAM) chip having at least a unit pair of a transistor and a capacitor and a flash memory chip for a unit memory block having a string selection transistor, a ground selection transistor and cell transistors. The contact structure may include a bit line contact or a bit line contact pad, a storage contact pad and a contact plug making contact with the string selection transistor and the ground selection transistor. The lower insulation layer may have a flat upper surface and the contact structure may be positioned on the flat upper surface of the lower insulation layer.

The wiring structure 200 may make contact with the contact structure of the conductive structure 100 at an upper portion of the conductive structure 100 and may include an interconnection (not shown) and a metal wiring ML in the medium of an insulation interlayer.

For example, the metal wiring ML may include a signal line for transferring the data signals, a power line for applying an electric power to the conductive structure 100 and a ground line for electrically grounding the conductive structure 100. The metal wiring ML may be electrically connected to the contact structure of the conductive structure 100 through the interconnection, and thus, the metal wiring ML may communicate with the conductive structure 100 through the contact structure and the interconnection. The wiring structure may further include an upper passivation layer that is arranged at an upper portion of the metal wiring ML and a connection pad for electrically connecting the metal wiring ML with external signal sources.

The penetration electrode 300 may penetrate through the substrate 101a and may make contact with one of the contact structures of the conductive structure 100 and the interconnection of the wiring structure 200.

In example embodiments, the penetration electrode 300 may include an insulation pattern 310, a base layer 320, a dielectric gap 330, a barrier layer 340 and a conductive plug 350 in the through-hole 102a of the substrate 101a.

The insulation pattern 310 may electrically insulate the conductive plug 350 from the substrate 101a, to thereby prevent or inhibit the electrical short of the conductive plug 350. For example, the insulation pattern 310 may comprise any one of silicon oxide, silicon nitride, polyimide and compositions thereof that may be formed by a deposition process or a thermal oxidation process.

The base layer 320 may be arranged on an inside wall of the through-hole 102a through a solid reaction between a first material layer a (not shown) and a second material layer (not shown). When performing the solid reaction between the first and the second material layers, first materials of the first material layer and second materials of the second material layer may be chemically reacted into a product of the base layer 320 around a boundary surface of the first and the second material layers. In such a case, the base layer 320 may be positioned relatively close to the first material layer or the second material layer in accordance with the difference between the diffusion speeds of the first and the second materials. When one of the first and the second materials may be diffused into the other material, the space occupied by the diffused material may become gap. Thus, the gap between the base layer 320 and one of the first and the second material layers may also be provided due to the solid reaction. That is, the base layer 320 and the gap adjacent to the base layer 320 may be simultaneously formed by the solid reaction between the first and the second material layers. As a result, a gap may be provided around the conductive plug 350 and the gap may function as an additional dielectric member especially when the gap may be filled with air or may be vacuumized, thereby providing the dielectric gap 330 around the conductive structure 350. Therefore, the base layer 320 and the gap for the dielectric gap 330 may be generated simultaneously with each other due to the solid reaction, and the position of the dielectric gap 330 may vary the difference between the diffusion speeds of the first and the second materials.

In example embodiments, the dielectric gap 330 may be filled with a dry air, and thus, the dielectric characteristics of the dielectric gap 330 may be determined by physical properties of the dry air. For that reason, the name of the air gap may be used in place of or in conjunction with the dielectric gap sometimes hereinafter.

Any materials may be used as the first and second materials of the first and second material layers as long as the difference between the diffusion speeds thereof is sufficiently large in the solid reaction and the solid reaction between the first and the second materials may be easily conducted in fabricating the semiconductor chips. In example embodiments, the base layer 320 may comprise product materials of the solid reaction of the first and the second materials at a relatively low temperature.

Examples of the product materials may include any one of BeNi, BeCo, Co₃S₄, CoSe, CoTe, ZnS, PbS, CuS, AuPt, MoS₂, AlN, CdS, ZnAl₂O₄, Zn₂SiO₄, SrTiO₃, BaTiO₃ and combinations thereof. The above product materials may be examples. However, various materials may be utilized for the base layer as long as the gap and the base layer may be simultaneously formed due to the difference of the diffusion speeds, as would be known to one of the ordinary skill in the art.

The through-hole 102a may penetrate through the insulation interlayer (not shown) by which the conductive structure 101a and the wiring structure 200 may be electrically insulated from each other and the substrate 101a. Thus, the base layer 320 may be arranged on sidewalls of the insulation interlayer and the substrate 101a. In addition, the base layer 320 may include a bonding structure much denser and more stable than that of the first and the second material layers due to the solid reaction. Thus, the conductive plug 350 in the through-hole 102b may be more insulated from surroundings and may be prevented or inhibited from being diffused into the insulation interlayer.

A material having desirable insulation properties may be filled into the gap adjacent to the base layer 320, to thereby form the dielectric gap 330 and to improve the insulation characteristics of the penetration electrode 300. In example embodiments, the gap may be filled with air or may be vacuumized. However, various materials may be filled into the gap adjacent to the base layer 320 in accordance with characteristics and requirements of the integrated circuit devices.

Particularly, when the air gap is provided between the barrier layer 340 and the base layer 320, filling the gap without dry air may provide an additional dielectric member with the penetration electrode 300 without any deposition processes and photolithography processes, thereby facilitating the improvement on the insulation characteristics of the penetration electrode 300 at a minimal cost: Therefore, the insulation characteristics of the penetration electrode 300 may be sufficiently improved. Thus, the signal interferences between the neighboring penetration electrodes 300 may be decreased even though the gap distances between the neighboring penetration electrodes 300 is decreased due to the downsizing of the integrated circuit device 900. Further, the improved insulation characteristics of the penetration electrode 300 may also prevent the parasitic capacitance of the penetration electrode 300. Thus, the RC delay of the integrated circuit device 900 including the penetration electrode 300 may be sufficiently prevented or inhibited.

In example embodiments, the gap adjacent to the base layer 320 may be provided by a nano scale because the diffusion of the first and the second materials may be accomplished by an atomic unit. Thus, the dielectric gap 330 may be accurately controlled by an atomic unit and thus may have an accurate thickness measured by the nano scale.

The barrier layer 340 may enclose the conductive plug 350 and may include an anti-diffusion layer (not shown) for preventing or inhibiting conductive materials for the conductive plug 350 into the insulation interlayer and a glue layer (not shown) for adhering the conductive plug 350 to the insulation interlayer. Particularly, when the insulation interlayer may comprise oxide and the conductive plug 350 may comprise metal, the conductive plug 350 may be hardly adhered to the insulation interlayer. In such a case, the glue layer may accelerate the adherence of the conductive plug 350 to the insulation interlayer and may decrease contact resistance on a boundary surface between the conductive plug 350 and the insulation interlayer.

For example, the barrier layer 340 may include a single layer or a multilayer having any one material of titanium, titanium nitride, tantalum, tantalum nitride and compositions thereof.

The conductive plug 350 may be positioned in the through-hole 102a and may penetrate through the conductive structure 100 and/or the wiring structure 200. For example, the conductive plug 350 may comprise low-resistive metal and the data signals may be transferred via the conductive plug 350 through the substrate 101a. Thus, the conductive structures 100 and the wiring structures 200 arranged on different substrates 101a may electrically communicate with one another by the penetration electrodes 300. Examples of the low-resistive material for the conductive plug 350 may include copper (Cu), nickel (Ni) and/or tungsten (W). These may be used alone or in combinations thereof.

The conductive plug 350 may fully penetrate through the substrate 101a, the conductive structure 100 and the wiring structure 200 as shown in FIG. 2A. In contrast, the conductive plug 350 may partially penetrate through the substrate 101a and the conductive structure 100, and thus, make contact with the contact structure of the conductive structure 100 or with the metal line of the wiring structure 200 as shown in FIG. 2B.

For example, the conductive plug 350 may penetrate through the substrate 101a, an insulation layer covering the conductive structure 100 and an insulation interlayer covering the wiring structure 200, and may make contact with an upper conductive pattern 352 that may be arranged on an upper portion of the wiring structure 200. An upper surface of the wiring structure 200 may be covered with an upper passivation layer (not shown) and the conductive pattern 352 may be arranged on the upper passivation layer. Thus, the conductive plug 350 and the conductive pattern 352 may be electrically insulated from each other. Particularly, the conductive pattern 352 may also extend over an upper wiring (not shown), and thus, the penetration electrode 300 may function as a re-directional wiring in the integrated circuit device 900.

Although not shown in the figures, an additional plug may be further provided between the conductive pattern 352 and the wiring structure 200, and thus, the conductive pattern 352 may be electrically connected to the metal line of the wiring structure 200 via the additional plug.

The penetration electrode 300 may also be buried in the wiring structure 200 as shown in FIG. 2B in such a configuration that the conductive plug 350 may make contact with the metal line of the wiring structure 200. In such a case, an upper surface of the conductive plug 350 may be coplanar with upper surfaces of the insulation pattern 310, the base layer 320 and the barrier layer 340.

While the base layer 320 may be positioned on the insulation pattern 310 and the dielectric gap 330 may be interposed between the base layer 320 and the barrier layer 340, the relative positions of the base layer 320 and the dielectric gap 330 may be varied in accordance with the diffusion speed of the first and the second materials. That is, the dielectric gap 330 may also be interposed between the insulation pattern 310 and the base layer 320.

In addition, the base layer 320 and the dielectric gap 330 may be interposed between the barrier layer 340 and the conductive plug 350 merely by changing the processing order of the steps of Ruining the first and the second material layers and the step of forming the barrier layer.

The rear surface of the substrate 101a may be uniformly removed by a backside lapping process, e.g., a polishing process, and thus, the thickness of the substrate 101a may be reduced as compared with an initial substrate. A re-directional structure 400 may be arranged on the rear surface of the substrate 101a and may make contact with the penetration electrode 300. For example, a conductive pattern structure may be provided on the rear surface of the substrate as the re-directional structure 400. A first end portion of the re-directional structure 400 may make contact with the penetration electrode 300 and a second end portion of the re-directional structure 400 may make contact with a lower contact terminal 600 that will be described in detail hereinafter.

A rear insulation layer (not shown) may be further provided between the re-directional structure 400 and the rear surface of the substrate 101a. An opening through which a lower portion of the conductive plug 350 may be exposed may be prepared through the rear insulation layer. The re-directional structure 400 may make contact with the lower portion of the conductive plug 350 in the opening of the rear insulation layer.

The re-directional structure 400 may provide various ways to connect the penetration electrode 300 and the lower contact terminal 600, thereby improving design flexibility of the integrated circuit device 900.

While the conductive plug 350 and the re-directional structure 400 may be formed individually by an additional patterning process, the re-directional structure 400 may be formed integrally together with the conductive plug 350 in a body in the same process. For example, the conductive plug 350 and the re-directional structure 400 may be simultaneously formed together with each other by a single electroplating process.

A lower passivation layer 500 may be arranged on the rear surface of the substrate 101a, and thus the re-directional structure 400 may be covered with the lower passivation layer 500. In addition, the lower passivation layer 500 may compensate for the mechanical strength of the substrate 101a of which the thickness is reduced by the backside lapping process. The lower passivation layer 500 may include an under-fill layer for forming the lower contact terminal 600.

Thus, the lower passivation layer 500 may compensate for the strength of the thinner substrate 101a and protect the re-directional structure 400 from environments. The re-directional structure 400 may be exposed through the opening of the lower passivation layer 500 and the lower contact terminal 600 may make contact with the re-directional structure 400 in the opening of the lower passivation layer 500. External signals may be applied to the lower contact terminal 600.

An upper contact terminal 700 may be on the wiring structure 200 and on the conductive plug 350 of the penetration electrode 300 and may make contact with another penetration electrode (not shown) of another integrated circuit device. The lower and the upper contact terminals 600 and 700 may include a solder ball or a solder bumper.

The lower and the upper contact terminals 600 and 700 may be selectively provided in accordance with the structure and shape of the penetration electrode 300. Particularly, when the penetration electrode 300 is buried in the conductive structure 100 or in the wiring structure 200, and thus, may makes contact with the contact structure of the conductive structure 100 or with the metal line of the wiring structure 200, the penetration electrode 300 may not protrude from an upper portion of the integrated circuit device 900. In such a case, the upper contact terminal 700 may not be provided with the integrated circuit device 900. In addition, when the lower portion of the penetration electrode 300 of the integrated circuit device 900 makes contact with an upper contact terminal of a neighboring integrated circuit device that may be vertically stacked on the integrated circuit device 900, no lower contact terminal 600 may be provided with the integrated circuit device 900. Therefore, the lower and the upper contact terminals 600 and 700 may be provided with the integrated circuit device 900 in accordance with the stack structures and configurations of semiconductor packages.

External signals may be transferred to the contact terminals 600 or 700, and thus, may be transferred to the wiring structure 200 through the penetration electrode 300. The external signals may be transferred to the conductive structures 100 of the integrated circuit device 900 via the wiring structure 200. Particularly, a plurality of the integrated circuit devices 900 may be vertically stacked, and the upper and lower contact terminals 600 and 700 of a pair of the vertically neighboring integrated circuit devices may make contact with each other. Thus, the vertically neighboring integrated circuit devices may be electrically connected to each other through the penetration electrode connected to the contact terminal, thereby forming a chip-stack package.

According to the integrated circuit device 900 of example embodiments, the penetration electrode may include the dielectric gap or the gap 340 as an additional dielectric member, to thereby sufficiently prevent or inhibit signal interferences and parasitic capacitance between the neighboring penetration electrodes. Therefore, when the gap distance between the neighboring penetration electrodes is reduced due to the higher integration degree, the signal interferences and the parasitic capacitance may be sufficiently prevented or inhibited, and the integration circuit device 900 may be stably operated with higher reliability.

Method of Manufacturing the Integrated Circuit Device

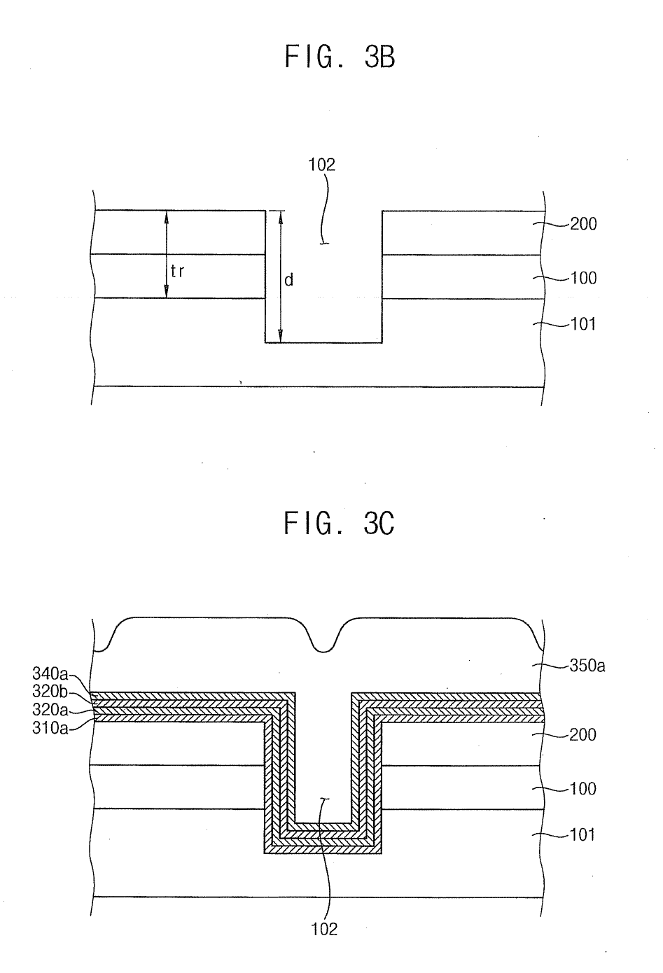

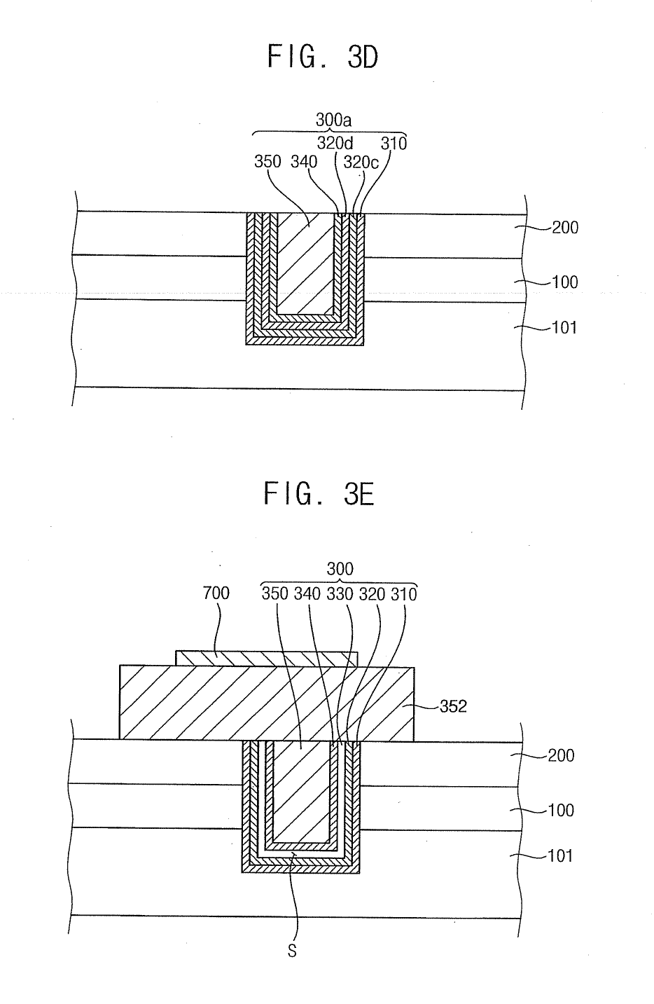

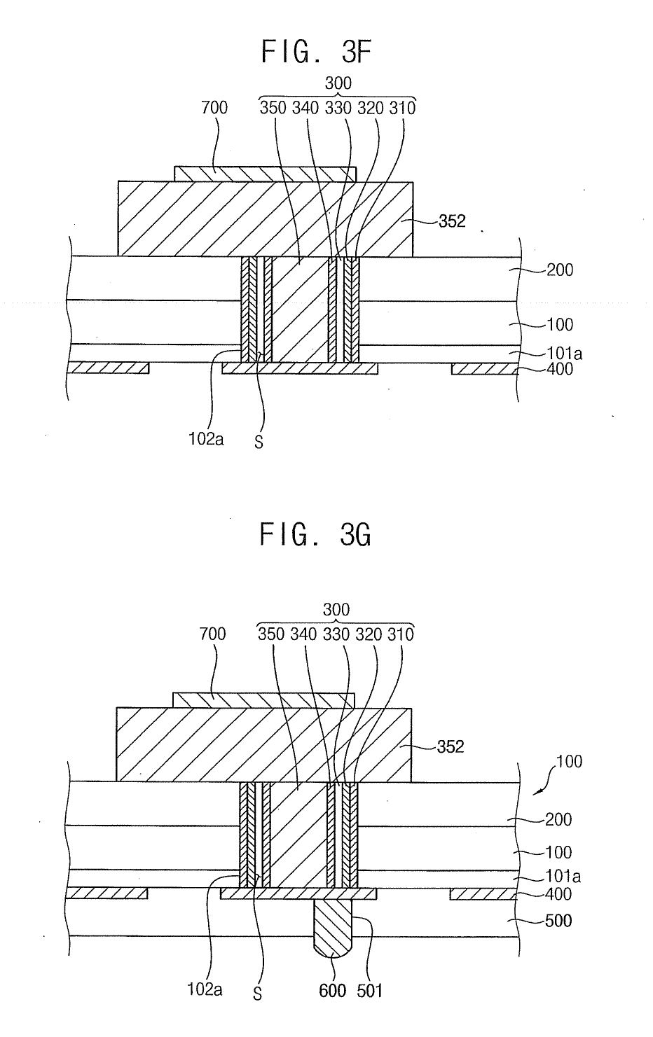

Hereinafter, the processing steps for a method of manufacturing the integrated circuit devices will be described in detail with reference to FIGS. 3A to 3E.

FIGS. 3A to 3E are cross-sectional views illustrating processing steps for a method of manufacturing the integrated circuit device 900 shown in FIGS. 1 and 2A in accordance with example embodiments of the present inventive concepts. The same processing concept may be applied to the method of manufacturing the integrated circuit device as shown in FIGS. 1 and 2A as the method of manufacturing the integrated circuit device shown in FIGS. 1 and 2B, as would be known to one of the ordinary skill in the art.

Referring to FIG. 3A, the conductive structure 100 including a plurality of semiconductor chips may be formed on the substrate 101. The conductive structure 100 may be covered with a planarized insulator (not shown) and the wiring structure 200 may be formed on the planarized insulator layer. The wiring structure 200 may be electrically connected to the conductive structure 100 and various signals may be transferred to the conductive structure 100 via the wiring structure 200.

The substrate 101 may include a semiconductor substrate, e.g., a wafer, and a plurality of semiconductor chips and contact structures may be formed on the substrate 101 by a semiconductor chip manufacturing process. Thus, the conductive structure 100 may include the semiconductor chips and the contact structures (not shown) on the substrate 101. The semiconductor chips and the contact structures may be electrically insulated from each other by a lower insulation layer (not shown). For example, the contact structure may include a contact plug and a contact pad. An upper surface of the lower insulation layer may be planarized, and the wiring structure 200 may be fowled on the upper surface of the lower insulation layer. For example, the semiconductor chip may include a pair of a transistor and a capacitor for a DRAM device and a plurality of transistors for a flash memory device.

The wiring structure 200 may be formed on the lower insulation layer and may include an interconnection (not shown) making electrical contact with the contact structure and a metal line (not shown) making contact with the interconnection and transferring signals. The interconnection and the metal line may be electrically insulated from each other by an insulation interlayer, and thus, the interconnection and the metal line may be formed into a multi-layered structure in the medium of the insulation interlayer. For example, the metal line may include a bit line and a word line for transferring signals to the conductive structure 100, a power line for applying an electric power to the semiconductor chips and a ground line for electrically grounding the semiconductor chips. A connection pad (not shown) may be formed over the metal line in a medium of an insulator and the metal line may be connected to the connection pad. External signals may be applied to the connection pad and may be transferred to the metal line of the wiring structure 200. An upper passivation layer (not shown) may be formed on the insulation interlayer, and thus, the wiring structure 200 and the conductive structure 100 may be protected from surroundings.

Accordingly, the conductive structure 100 and the wiring structure 200 may be stacked on the substrate 101 in the medium of a plurality of the insulation layers and the insulation interlayers.

Referring to FIG. 3B, the conductive structure 100 and the wiring structure 200 may be partially removed from the substrate 101, thereby forming a recess 102 through which the substrate 101 may be partially exposed. Thus, the recess 102 may be defined by sidewalls of the conductive structure 100 and the wiring structure 200, and a sidewall and a bottom of the substrate 101.

The recess 102 may be formed to have a width corresponding to that of the penetrating electrode 300 and a depth d greater than a thickness of the thinner substrate 101a. Hereinafter, the thinner substrate 101a refers to substrate 101 of which the thickness is reduced by the backside lapping process, which will be described in detail hereinafter. That is, the depth d of the recess 102 may be greater than a reduced thickness Tr of the thinner substrate 101a. When the recess 102 does not have a sufficient depth d, a relatively large amount of the rear portion of the substrate 101 will need to be removed in the backside lapping process so that the penetration electrode 300 may protrude out of the rear surface of the substrate 101, thereby increasing the process time of the backside lapping process. In contrast, when the recess 102 has an excessively great depth d, the aspect ratio of the recess 102 may be so large that various process defects, e.g., gaps, are likely to be generated when forming the penetration electrode in the recess in a subsequent process.

The recess 102 may be formed by various processes, e.g., a dry etching process, a wet etching process and a laser drilling process. Because the wiring structure 200 including conductive metals and the substrate 101 including semiconductor materials, e.g., silicon (Si), need be etched off in the same etching process for forming the recess 102, the etching conditions of the etching process need be varied with ease in accordance with to-be-etched materials. For that reason, a dry etching process or a laser drilling process may be used for forming the recess 102 rather than the wet etching process. The dry etching process for forming the recess 102 may include a reactive ion etching (RIE) process, a sputtering etching process and a plasma etching process. Particularly, a mask pattern and photolithography process may be not needed for the laser drilling process, and the laser drilling process may control the width w and the depth d of the recess 102. Thus, the recess 102 may be formed by the laser drilling process in example embodiments.

Referring to FIG. 3C, an insulation layer 310a, a first material layer 320a, a second material layer 320b, a preliminary barrier layer 340a and a conductive layer 350a may be sequentially formed on the wiring structure 200 according to a surface profile of the depth 102.

For example, the insulation layer 310a may be uniformly formed on an upper surface of the wiring structure 200 and the sidewall and bottom of the recess 102 by a chemical vapor deposition (CVD) process or a physical vapor deposition (PVD) process. The first layer 310a may include silicon oxide, silicon nitride and polyimide. The insulation layer 310a may electrically insulate the conductive plug 350 from the substrate 101, thereby preventing or inhibiting an electrical short of the penetration electrode 300.

Otherwise, the insulation layer 310a may be formed merely on sidewalls and a bottom surface of the recess 102 corresponding to the substrate 101 by a thermal oxidation process just like a spacer.

The first and the second material layers 320a and 320b may be formed on the insulation layer 310a according to the surface profile of the recess 102 by one of a PVD process, a CVD process and a sputtering process.

The first and second material layers 320a and 320b may be formed into the base layer 320 and the gap may be formed as the dielectric gap 330 in a subsequent process. Particularly, the first and second material layers 320a and 320b may experience a solid reaction under heat of the subsequent process, and thus a third layer and the gap may be produced at the boundary region of the first and second material layers 320a and 320b by the solid reaction. The third layer of the product of the solid reaction may function as the base layer 320. Therefore, the first and the second material layers 320a and 320b may include reactants of the base layer 320. Various materials may be used for the first and the second material layer 320a and 320b as long as the materials have different diffusion speeds. The gap may be formed at the boundary region of the first and the second material layers due to the solid reaction. Thereafter, the gap may be filled with insulation materials and the dielectric gap 330 may be formed adjacent to the base layer 320.

For example, when the base layer 320 include zinc aluminum oxide (ZnAl₂O₃), the first and the second material layers 320a and 320b may include zinc oxide (ZnO) and aluminum oxide (Al₂O₃), respectively. Materials having a relatively higher diffusing speed may be diffused into the other materials having relatively lower diffusing speed. Thus, the gap may be fowled closely to a material layer having the materials having a relatively higher diffusing speed. Therefore, the position of the dielectric gap 330 may be varied according to the difference between the diffusion speeds of atoms of the materials in the first and the second material layers 320a and 320b.

The preliminary barrier layer 340a may be formed on the second material layer 320b according to the surface profile of the recess 102. The preliminary barrier layer 340a may prevent or inhibit materials of the conductive layer 350a from diffusing into the insulation layer 310a and the substrate 101 when performing a deposition process for forming the conductive plug 350.

In addition, the preliminary barrier layer may improve the adherence between the conductive layer 350a and the insulation layer 310a and reduce electrical resistance at the boundary area of the conductive layer 350a and the insulation layer 310a. Thus, the preliminary barrier layer 340a may include a bi-layer structure having an anti-diffusion layer and a glue layer.

Particularly, the preliminary barrier layer 340a may include the same material as the conductive layer 350a to thereby reduce the electrical resistance at the boundary area of the conductive layer 350a and the insulation layer 310a. For example, when the conductive layer 350a includes tungsten (W), the preliminary barrier layer 340a may include a single layer of tungsten nitride (WN) and a bi-layer of tungsten (W) and tungsten nitride (WN). Thus, the composition of the preliminary barrier layer 340a may be varied according to the composition of the conductive layer 350a. In example embodiments, the preliminary barrier layer 340a may include a single layer or a multi-layer including titanium (Ti), titanium nitride (TiN), tantalum (Ta), tantalum nitride (TaN) and compositions thereof

An excessively large thickness of the preliminary barrier layer 340a may cause an increase in the electrical resistance at the boundary area, and thus, the preliminary barrier layer 340a may be formed to be as thin as possible. For that reason, the preliminary barrier layer 340a may be formed by a CVD process and a sputtering process.

The conductive layer 350a may be faulted on the preliminary barrier layer 340a to a sufficient thickness to fill up the recess 102 by an electroplating process or a deposition process, e.g., a CVD process and a PVD process.

When the sidewalls of the recess 102 may not be uniform or the recess 102 may have a greater aspect ratio, various deposition defects, e.g., gaps and seams, may be generated in the recess 102 in the deposition process. Thus, the conductive layer 350a may be formed by the deposition process when the aspect ratio of the recess 102 is sufficiently small and by the electroplating process when the aspect ratio of the recess 102 is excessively great.

In example embodiments, the conductive layer 350a may be formed by the electroplating process using the preliminary barrier layer 340a as a seed layer. In such a case, the conductive layer 350a may be grown from the preliminary barrier layer 340a at the bottom of the recess 102 by the electroplating process to such a degree that the recess 102 may be filled up with the electroplated conductive layer 350a.

Referring to FIG. 3D, the conductive layer 350a, the preliminary barrier layer 340a, the second and the first material layers 320b and 320a and the insulation layer 310a may be partially removed from the wiring structure 200 by a planarization process until an upper surface of the wiring structure 200 may be exposed, thereby fainting a preliminary penetration electrode having the insulation pattern 310, first and second material patterns 320 and 320d, a barrier layer 340 and the conductive plug 350 in the recess 102.

For example, upper portions of the conductive layer 350a, the preliminary barrier layer 340a, the second and the first material layers 320b and 320a and the insulation layer 310a may be removed from the wiring structure 200 by a chemical mechanical polishing (CMP) process or an etch-back process, until the conductive layer 350a, the preliminary barrier layer 340a, the second and the first material layers 320b and 320a and the insulation layer 310a may remain just merely in the recess 102.

Therefore, the insulation pattern 310, the first and the second material patterns 320c and 320d and the barrier layer 340 may be sequentially formed on the sidewalls and the bottom of the recess 102 and may enclose the conductive pattern 350 in the recess 102. Thus, the preliminary penetration electrode 300a may include the conductive plug 350 enclosed by the insulation pattern 310, the first and the second material patterns 320c and 320d and the barrier layer 340 in the recess 102.

Referring to FIG. 3E, the conductive pattern 352 and the upper contact terminal 700 may be formed on the preliminary penetration electrode 300a and the wiring structure 200 simultaneously with the base layer 340 and the gap S in the recess 102.

For example, an insulation pattern (not shown) having a trench may be formed on the wiring structure 200 and the conductive plug 350 of the preliminary penetration electrode 300a may be exposed through the trench. A conductive layer (not shown) may be fowled on the insulation pattern to a sufficient thickness to fill up the trench. An upper portion of the conductive layer may be planarized until an upper surface of the insulation pattern is exposed. Therefore, the conductive pattern 352 may be formed in the trench of the insulation pattern and may extend on the wiring structure 200 in a predetermined or given direction.

For example, the conductive layer may be formed by a CVD process and may make contact with the conductive plug 350 and the signals may be transferred to the conductive pattern 352 through the conductive plug 350. Thus, the conductive layer may include a material having a relatively low electric resistance at the boundary area of the conductive layer and the conductive pattern 350. The conductive pattern 352 may function as a re-directional pattern, and thus, the conductive plug 350 may be positioned irrespective of the metal line of the wiring structure 200. That is, the penetration electrode 300 may be positioned irrespective of the metal line of the wiring structure 200 due to the conductive pattern 352.

Then, the upper contact terminal 700 may be foal red on the conductive pattern 352. For example, an upper terminal layer (not shown) may be formed on the conductive pattern 352 and a reflow process may be performed on the upper terminal layer. Therefore, the upper terminal layer may be formed into the upper contact terminal 700, which although not shown, may be shaped as a solder ball. The upper terminal layer may include materials having improved conductivity and adherence.

Because the conductive pattern 352 and the upper contact terminal 700 may be formed at a higher temperature, the first and second material patterns 320c and 320d may experience the solid reaction under heat. Thus, the materials of the first and the second material patterns 320c and 320d (see FIG. 3D) may be diffused into each other at the diffusion speed thereof. In such a case, materials having a relatively higher diffusing speed may be diffused into the other materials with a relatively lower diffusing speed. Thus, the gap S may be formed closely to a material layer having the materials with a relatively higher diffusing speed.

In addition, products of the solid reaction may be generated to having the material with a relatively lower diffusing speed, thereby forming the base layer 320 simultaneously with the gap S. That is, the solid reaction between the first and the second material patterns 320c and 320d may generate the gap S and the base layer 320 in the recess. Therefore, the position of the gap S may be varied according to the difference between the diffusion speeds of atoms of the materials in the first and the second material patterns 320c and 320d.

For example, when zinc oxide layer and aluminum oxide layer may make contact with each other as the first and the second material patterns 320c and 320d, respectively, a solid-solid reaction may be conducted between zinc oxide and aluminum oxide under heat generated in the process for forming the conductive pattern 352 and the upper contact terminal 700. Thus, a zinc aluminum oxide (ZnAl₂O₄) layer may be formed on the insulation pattern 310 as the base layer 320 and the gap S may be formed between the zinc oxide layer and the aluminum oxide layer by a nano scale due to the difference of diffusion speeds of a zinc oxide layer and the aluminum oxide.

The gap S may be formed into an additional dielectric layer enclosing the conductive plug 350. For example, the gap S may be filled with air or may be vacuumed. Thus, the gap S may be formed into the dielectric gap 330 enclosing the conductive plug 350. As a result, the recess 102 may be filled with the insulation pattern 310, the base layer 320, the dielectric gap 330, the barrier layer 340 and the conductive plug 350.

For example, the base layer 320 may include at least one material selected from the group consisting of BeNi, BeCo, Co₃S₄, CoSe, CoTe, ZnS, PbS, CuS, AuPt, MoS₂, AlN, CdS, ZnAl₂O₄, Zn₂SiO₄, SrTiO₃, BaTiO₃ and combinations thereof. Thus, the first and the second material patterns 320c and 320d may include reactant materials of the solid reaction for forming the base layer 320. The materials of the base layer 320 may be disclosed and various materials may be utilized for the base layer as long as the gap S and the base layer 320 may be simultaneously fowled due to the difference of the diffusion speeds thereof, as would be known to one of the ordinary skill in the art.

While the solid reaction of the first and the second material patterns 320c and 320d may be conducted by the heat generated from the process for forming the conductive pattern 352 and the upper contact terminal 700, the solid reaction of the first and the second material patterns 320c and 320d may also be conducted by heat generated from any other heat sources known to ordinary skill in the art.

For example, the solid reaction may also be conducted by heat generated from various deposition processes and photolithography processes after forming the preliminary penetration electrode 300a. Particularly, various unit processes may be performed after the formation of the preliminary penetration electrode 300a so as to complete the integrated circuit device 900, and a sufficient amount of heat may be generated from each unit processes. The solid reaction may also be conducted by the heat generated from the unit processes.

In addition, while the base layer 320 is formed on the insulation pattern 310 and the air gap 330 is interposed between the barrier layer 340 and the base layer 320, the configurations of the base layer 320 and the air gap 330 may be varied in accordance with the diffusion speeds of the materials of the first and second material patterns 320c and 320d. That is, the air gap 330 may be interposed between the insulation pattern 310 and the base layer 320, and the base layer 320 may make contact with the barrier layer 340 in accordance with the diffusion speeds of the reactant materials of the solid reaction.

Further, the first and the second material patterns 320c and 320d may also be formed between the barrier layer 340 and the conductive plug 350. In such a case, the air gap 330 may be formed between the conductive plug 350 and the barrier layer 340. The air gap 330 interposed between the conductive plug 350 and the barrier layer 340 may be easily accomplished by changing the stack order of the preliminary barrier layer 340a and the material layers 320a and 320b in the processing step described in detail with reference to FIG. 3C.

That is, the preliminary barrier layer 340a may be firstly formed on the insulation layer 310a and then the first and the second material layer 320a and 320b may be formed on the preliminary barrier layer 340a. Thus, the insulation pattern 310, the barrier layer 340 and the base layer 320 may be sequentially stacked on the sidewall of the recess 102 and the base layer 320 may be spaced apart from the conductive plug 350 by the air gap 330.

Although not shown in the figures, the insulation pattern 310 and the first and the second material patterns 320a and 320b may also be formed merely on the sidewalls of the recess 102 corresponding to the substrate 101, except on the sidewalls of the sidewalls of the wiring structure 200 and the conductive structure 100. In such a case, the base layer 320 and the air gap 330 may be formed just merely between the conductive plug 350 and the insulation pattern 310 and may not be formed between the wiring structure 200 and the conductive plug 350 or between the conductive structure 100 and the conductive plug 350. That is, the wiring structure 200 and the penetration electrode 300 may make contact with each other, and thus, no contact terminal may be needed. Particularly, the connection pad of the wiring structure 200 may make direct contact with the conductive plug 350 of the penetration electrode 300.

Referring to FIG. 3F, the substrate 101 may be formed to be thinner by a backside lapping process in such a manner that the conductive plug 350 may protrude from the rear surface and the re-directional structure 400 may be formed on the rear surface of the substrate 101.

For example, the rear surface of the substrate 101 may be polished or etched off in the backside lapping process until a lower portion of the recess 102 may be exposed. Thus, the recess 102 may be transformed into a through-hole 102a penetrating into the thinner substrate 101a and the insulation pattern 310, the base layer 320, the air gap 330, the barrier layer 340 and the conductive plug 350 may be exposed. That is, the insulation pattern 310, the base layer 320, the air gap 330, the barrier layer 340 and the conductive plug 350 may penetrate through the thinner substrate 101a, thereby forming the penetration electrode 300. A lower insulation layer (not shown) may be formed on the rear surface of the thinner substrate 101a and the lower insulation layer may be patterned into a lower insulation pattern having an opening through which the conductive plug 350 may be exposed.

Then, a re-directional layer (not shown) including a conductive material may be formed on the lower insulation pattern to a sufficient thickness to fill up the opening of the lower insulation pattern. Thus, the re-directional layer may make contact with the conductive plug 350 of the penetration electrode 300. Thereafter, the re-directional layer may be patterned into various shapes in a direction, thereby forming the re-directional structure 400 making contact with the penetration electrode 300.

Because the re-directional structure 400 may be patterned in an expected direction, the penetration electrode 300 may be arranged in the integrated circuit device 900 without position limitations, thereby allowing various modifications to a stack structure of the integrated circuit devices 900.

Referring to FIG. 3G a lower passivation layer 500 may be formed on the rear surface of the thinner substrate 101a to cover the re-directional structure 400. The lower passivation layer 500 may include an opening 501 through which the re-directional structure 400 may be exposed. The lower contact terminal 600 may be formed on the lower passivation layer 500 in such a manner that the re-directional structure 400 may make contact with the re-directional structure 400, thereby completing the integrated circuit device 900.

For example, the lower passivation layer 500 may include insulating materials, thereby preventing or inhibiting an electrical short of the lower contact terminal 600. Examples of the insulative material for the lower passivation layer 500 may include photoresist (PR), photo solder resist (PSR), epoxy molding compound, an oxide and/or an under-fill material. These may be used alone or in combinations thereof. The lower passivation layer 500 may be formed on the rear surface of the thinner substrate 101a by a deposition process. The lower passivation layer 500 may be partially removed from the rear surface corresponding to the re-directional structure 400, thereby forming the opening 501 of the lower passivation layer 500.

Conductive materials may be filled in the opening 501 of the lower passivation layer 500, and thus, the lower contact terminal 600 may be formed in the opening 501 and make contact with the re-direction structure 400 in the opening 501. For example, the lower contact terminal 600 may include a solder ball and a solder bumper (not shown).

While the conductive structure 100 and the wiring structure 200 may be formed on the substrate 101 and the preliminary penetration electrode 300a may be formed to penetrate the conductive structure 100 and the wiring structure 200, any other changes of processing orders would be allowable according to processing conditions and device requirements. For example, the wiring structure 200 may also be formed after the formation of the preliminary penetration electrode 300a.

Particularly, the conductive structure 100 may be formed on the substrate 101 and the conductive structure 100 and the substrate 101 may be partially removed by an etching process, to thereby form the recess. Then, the recess may be filled with the insulation pattern, the base layer, the dielectric gap, the barrier layer and the conductive plug, thereby forming the preliminary penetration electrode in the recess. The wiring structure 200 may be formed on the conductive structure 100 and the preliminary penetration electrode. The rear surface of the substrate 101 may be polished by the backside lapping process in such a manner that the recess is formed in the through-hole and the preliminary penetration electrode may be exposed through the through hole, thereby fowling the penetration electrode in the through hole.

In such a case, the penetration electrode may penetrate through the conductive structure 100 and the substrate 101 and make contact with the metal line of the wiring structure 200. That is, the penetration electrode may not protrude from an upper surface of the wiring structure 200. Therefore, the processing step of forming the conductive pattern 352 may be omitted. In similar ways, the preliminary penetration electrode may be formed merely in the recess of a bare substrate 101 on which no conductive structure 100 and no wiring structure 200 may be formed. Then, the conductive structure 100 and the wiring structure 200 may be sequentially formed on the substrate 101 including the preliminary penetration electrode. Thus, the penetration electrode may penetrate merely through the substrate and make contact with the contact structure of the conductive structure 100.

Therefore, the processing order of the step of forming the preliminary penetration electrode, the step of forming the conductive structure and the step of forming the wiring structure may be varied in accordance with the processing conditions and the device requirements of the integrated circuit device 900.

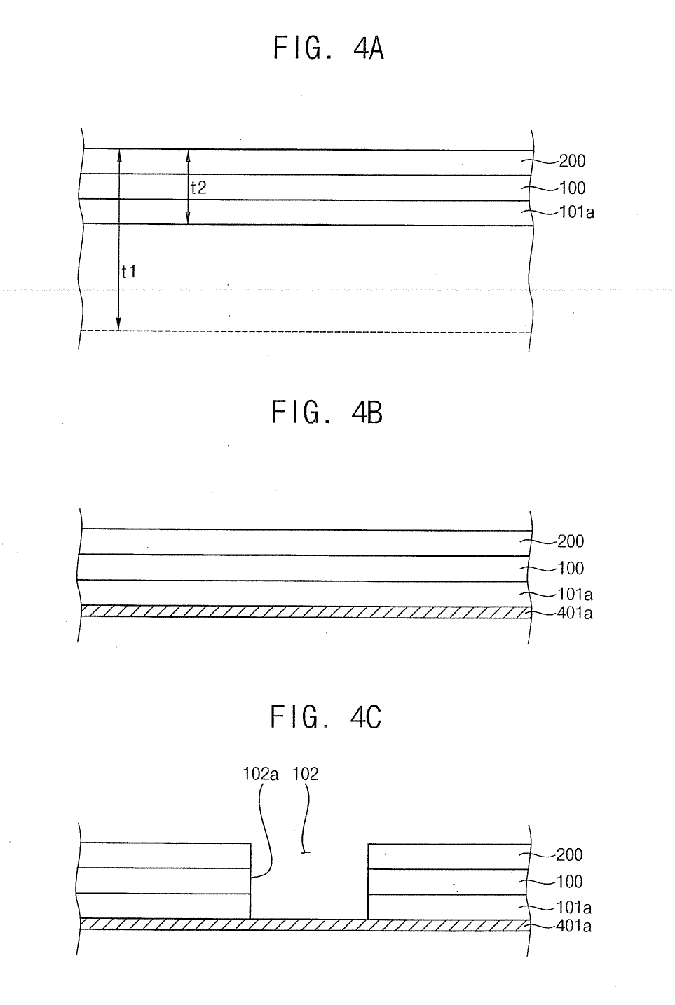

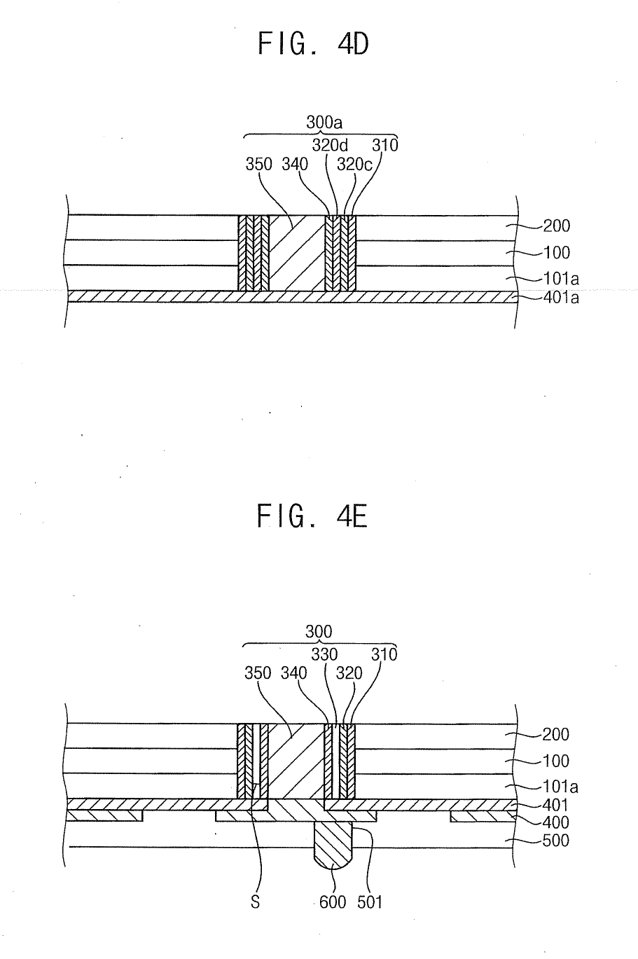

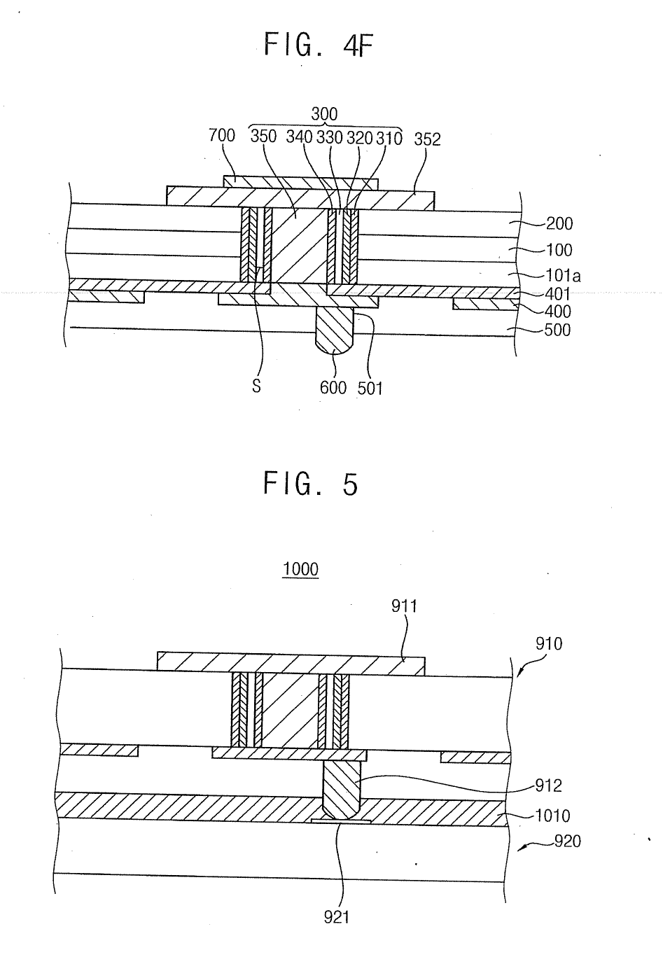

FIGS. 4A to 4F are cross-sectional views illustrating processing steps for a method of manufacturing the integrated circuit device 900 shown in FIGS. 1 and 2A in accordance with example embodiments of the present inventive concepts.

The method of manufacturing the integrated circuit device may be substantially the same as the previously described method of example embodiments except that the processing steps for reducing the thickness of the substrate and the processing steps for forming the lower insulation layer and the re-directional layer on the rear surface of the substrate are performed prior to the processing steps for forming the conductive pattern and the upper contact terminal. Thus, in FIGS. 4A to 4F, the same reference numerals denote the same elements in FIGS. 3A to 3G.

At first, the conductive structure 100 and the wiring structure 200 may be fowled on the substrate 101 by substantially the same process as described in detail with reference to FIG. 3A.

Then, as shown in FIG. 4A, the whole rear surface of the substrate 101 may be polished by the backside lapping process and the thickness of the substrate 101 may be reduced in such a manner that a first thickness t1 of the substrate 101 may be decreased to a second thickness t2. Hereinafter, the numeral 101a denotes the reduced substrate having the second thickness t2 in FIG. 4A. The thickness reduction of the substrate may be performed substantially in the same way as described in detail with reference to FIG. 3E, and thus, any detailed descriptions on the thickness reduction of the substrate will be omitted. Particularly, the thinner substrate 101a may have a sufficiently small thickness, and thus, a larger number of the integrated circuit devices 900 may be stacked in a stack structure.

Referring to FIG. 4B, a lower insulation layer 401a may be formed on the rear surface of the thinner substrate 101a. The base layer of the penetration electrode and the lower contact terminal may be electrically insulated by the lower insulation layer 401a. In addition, the mechanical strength of the thinner substrate 101a may be reinforced by the lower insulation layer 401a, and thus, the thinner substrate 101a may be prevented or inhibited from being broken in subsequent processes. For example, the lower insulation layer 401a may include silicon oxide and silicon nitride.

Referring to FIG. 4C, the through-hole 102a may be fowled through portions of the conductive structure 100, the wiring structure 200 and the thinner substrate 101a until an upper surface of the lower surface may be exposed, to thereby form a recess 102 defined by the exposed lower insulation layer 401a and the sidewalls of the conductive structure 100, the wiring structure 200 and the thinner substrate 101a.

For example, the conductive structure 100, the wiring structure 200 and the thinner substrate 101a may be partially removed by the same process as described with reference to FIG. 3B until the upper surface of the lower insulation layer 401a may be exposed. Therefore, the lower insulation layer 401a may function as an etch stop layer for etching the thinner substrate 101a.

As compared with another example embodiment, the etching process may be performed against the thinner substrate 101a rather than against the substrate 101, to thereby facilitate the formation of the through-hole 102a. In addition, the depth of the through-hole 102a may be relatively small, and thus, the through-hole 102a may be formed to have a uniform sidewall.

Referring to FIG. 4D, the recess 102 may be filled with the insulation pattern 310, the first and the second material patterns 320c and 320d, the barrier layer 340 and the conductive plug 350, thereby forming the preliminary penetration electrode 300a in the recess 102. The preliminary penetration electrode 300a may be formed by substantially the same deposition process and the planarization process as described in detail with reference to FIGS. 3C to 3E, and thus further descriptions on the formation of the preliminary penetration electrode will be omitted.

Referring to FIG. 4E, the lower insulation layer 401a may be patterned into the lower insulation pattern 401 through which the conductive plug 350 of the preliminary penetration electrode 300a may be exposed, thereby fowling the penetration electrode 300 in the through-hole 102a. The re-directional structure 400 may be formed on the lower insulation pattern 401, and thus, the exposed conductive plug 350 of the penetration electrode 300 may make contact with the re-directional structure 400. The re-directional structure 400 may be covered with the lower passivation layer 500.

For example, the lower insulation layer 401a may be partially removed from the rear surface of the thinner substrate 101a by a photolithography process, thereby forming the lower insulation pattern 401 having an opening through which the conductive plug 350 may be exposed. Then, the re-directional layer (not shown) may be formed on the lower insulation pattern 401 to a sufficient thickness to fill the opening of the lower insulation pattern 401.

The re-directional layer may include conductive materials and may be formed by a CVD process or an electroplating process. In example embodiments, the CVD process may include a chemical vapor deposition process and a physical vapor deposition (PVD) process, and the electroplating process may include a wet electroplating process. Examples of the conductive materials for the re-directional layer may include copper (Cu), aluminum (Al), nickel (Ni), platinum (Pt), silver (Ag) and/or gold (Au). These may be used alone or in combinations thereof.

The re-directional layer may be patterned into the line-shape re-directional structure 400 and the contact terminal 600 may make contact with the re-directional structure 400 in a subsequent process. Thus, external signals may be transferred to the penetration electrode 300 through the re-directional structure 400 and the lower contact terminal 600. In example embodiments, the conductive material for the re-directional structure 400 may include the same materials of the conductive plug 350, thereby minimizing or reducing the electrical resistance between the re-directional structure 400 and the conductive plug 350.

In addition, the re-directional structure 400 may have the same shape and size as the thinner substrate 101a and thus the re-directional structure 400 and the thinner substrate 101a may have substantially the same shear surface. Therefore, the assembly of the thinner substrate 101a and the re-directional structure 400 may have a sufficient thickness to endure bending force and/or torsion force applied to the thinner substrate 101a in a subsequent process. That is, the mechanical strength of the thinner substrate 101a may be sufficiently reinforced against the bending and torsion of the thinner substrate 101a.

The lower passivation layer 500 may be fowled on the re-directional structure 400, and thus, the re-directional structure 400 may be sufficiently covered with the lower passivation layer 500. The lower passivation layer may be partially removed to thereby form an opening 501 through which the re-directional structure 400 may be partially exposed. The opening 501 of the lower passivation layer 500 may be filled with the lower contact terminal 600. The re-directional structure 400, the lower passivation layer 500 and the lower contact terminal 600 may be formed substantially by the same process as described in detail with reference to FIG. 3G, and thus, any further detailed descriptions will be omitted.

Referring to FIG. 4F, the conductive pattern 352 and the upper contact terminal 700 may be formed on the penetration electrode 300. The conductive pattern 352 may make contact with the conductive plug 350 of the penetration electrode 300, and the upper contact terminal 700 may be electrically connected to the conductive pattern 352. The conductive pattern 352 and the upper contact terminal 700 may be formed substantially by the same process as described in detail with reference to FIG. 3F, and thus, any further detailed descriptions will be omitted.

As shown in FIGS. 4E and 4F, because the lower passivation layer 500, the lower contact terminal 600 and the upper contact terminal 700 are formed at a higher temperature, the first and second material patterns 320c and 320d of the preliminary penetration electrode 300a may experience the solid reaction under heat.

Thus, the materials of the first and the second material patterns 320c and 320d may be diffused into each other at the diffusion speed thereof, thereby forming the base layer 320 simultaneously with the gap S, as described in detail with reference to FIG. 3E. The gap S may be filled with air or may be vacuumized, thereby forming the dielectric gap 330 enclosing the conductive plug 350. Therefore, the dielectric characteristics of the penetration electrode 300 may be sufficiently improved as much as the dielectric property of the dielectric gap 330.

While the conductive structure 100 and the wiring structure 200 may be formed on the substrate 101 and the preliminary penetration electrode 300a may be formed to penetrate the conductive structure 100 and the wiring structure 200, any other changes of processing orders would be allowable according to processing conditions and device requirements. For example, the wiring structure 200 may also be formed after the formation of the preliminary penetration electrode 300a.

In such a case, the penetration electrode may penetrate through the conductive structure 100 and the substrate 101 and make contact with the metal line of the wiring structure 200. That is, the penetration electrode may not protrude from an upper surface of the wiring structure 200. Therefore, the processing step of forming the conductive pattern 352 may be omitted.

In addition, the preliminary penetration electrode may be formed merely in the recess of the bare substrate 101 on which no conductive structure 100 and no wiring structure 200 may be formed. Then, the conductive structure 100 and the wiring structure 200 may be sequentially formed on the substrate 101 including the preliminary penetration electrode. Thus, the penetration electrode may penetrate merely through the substrate and make contact with the contact structure of the conductive structure 100.

Therefore, the processing order of the step of forming the preliminary penetration electrode, the step of forming the conductive structure and the step of forming the wiring structure may be varied in accordance with the processing conditions and the device requirements of the integrated circuit device 900.

According to the methods for manufacturing the integrated circuit device, a pair of material layers having a sufficient difference of diffusion speeds may be formed between the insulation layer and the conductive plug. Thus, the pair of the material layers may be formed into the base layer and the gap by the solid reaction under heat generated from the subsequent processes. The gap may be filled with dielectric materials, e.g., a dry air, or may be vacuumized, thereby forming an additional dielectric gap around the conductive plug of the penetration electrode. Therefore, when the gap distance between the neighboring penetration electrodes may be reduced due to the higher integration degree, the signal interferences and the parasitic capacitance may be sufficiently prevented or inhibited and the integration circuit device 900 may be stably operated with higher reliability.

Stack Package and Method of Manufacturing the Same

FIG. 5 is a cross-sectional view illustrating a stack package in which a plurality of the integrated circuit devices shown in FIGS. 1 and 2A is stacked in accordance with example embodiments of the present inventive concepts.

Referring to FIG. 5, the stack package 1000 in accordance with example embodiments of the present inventive concepts may include first and second integrated circuit devices 910 and 920 that may be stacked vertically.

In example embodiments, the first integrated circuit device 910 may have the same structure as the integrated circuit device shown in FIGS. 1 and 2A, and the second integrated circuit device 920 under the first integrated circuit device 910 may have a structure different from the integrated circuit device shown in FIGS. 1 and 2A. However, the second integrated circuit device 920 may also have the same structure as the integrated circuit device shown in FIGS. 1 and 2A. For example, the second integrated circuit device 920 may include a master chip of the stack package 1000 and the first integrated circuit device 910 may include a slave chip of the stack package 1000 that may be electrically connected to the master chip.

The connection pad 921 of the second integrated circuit device 920 may make contact with the lower contact terminal 912 of the first integrated circuit device 910. In the first integrated circuit device 910, the metal line may be connected to the penetration electrode through the conductive pattern 911 and the penetration electrode may be connected to the lower contact terminal 912 through the re-directional structure. The connection pad 921 of the second integrated circuit device 920 may make contact with the metal line of the wiring structure of the second integrated circuit device 920. Thus, the first and the second integrated circuit devices 910 and 920 may be electrically connected to each other by a serial contact of the connection pad 921 of the second integrated circuit device 920, the lower contact terminal 912 of the first integrated circuit device 910 and the penetration electrode of the first integrated circuit device 910.

Further, a filling member 1010 may be interposed between the first and the second integrated circuit devices 910 and 920. The first and the second integrated circuit devices 910 and 920 may be protected from surroundings and the thermal stresses to the stack package 1000 may be absorbed into the filling member 1010. For example, the filling member 1010 may include an under-fill resin having desirable insulation characteristics.

Particularly, the lower contact terminal 912 of the first integrated circuit device 910 may be arranged at arbitrary positions by the re-directional structure, and thus, the penetration electrode of the first integrated circuit device 910 may more easily make contact with the connection pad 921 of the second integrated circuit device 920 although the first and the second integrated circuit devices 910 and 920 may not be correctly aligned with each other in the stack package 1000. In case that the first and the second integrated circuit devices 910 and 920 may have the same structures, the upper contact terminal of the second integrated circuit device 920 may be used in place of or in conjunction with the connection pad 921, as would be known to one of the ordinary skill in the art.

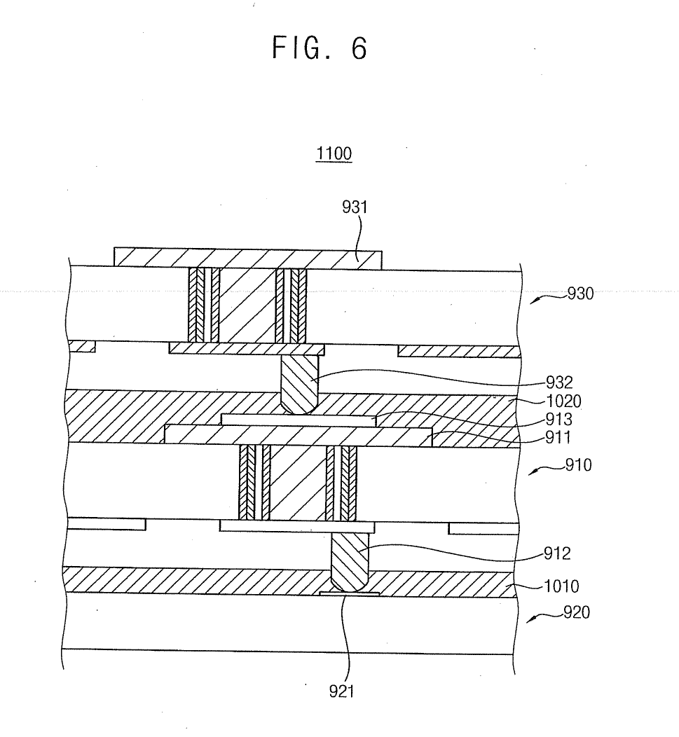

FIG. 6 is a cross-sectional view illustrating a stack package in which a plurality of the integrated circuit devices shown in FIGS. 1 and 2A is stacked in accordance with example embodiments of the present inventive concepts. The stack package 1100 in FIG. 6 may further include a third integrated circuit device 930 stacked on the stack package 1000 shown in FIG. 5. The first and the third integrated circuit devices 910 and 930 may have the same structures.

Referring to FIG. 6, the third integrated circuit device 930 may be stacked on the first integrated circuit device 910 in such a manner that the upper contact terminal 913 may make contact with the lower contact terminal 932 of the third integrated circuit device 930. Thus, the first, second and third integrated circuit devices 910, 920 and 930 may be electrically connected in series in the stack package 1100 through the contact terminals and the penetration electrode thereof.

The metal line of the third integrated circuit device 930 may be connected to a third penetration electrode through a third conductive pattern 931 and the third penetration electrode may be connected to the third lower contact terminal 932. The third lower contact terminal 932 may make contact with a first upper contact terminal 913 of the first integrated circuit device 910 and thus may be electrically connected to the first conductive pattern 911. The first conductive pattern 911 may be electrically connected with the metal line of the first integrated circuit device 910.

Accordingly, the metal lines of the first and the third integrated circuit devices 910 and 930 may be electrically connected to each other through the third penetration electrode. The stack structure of the first and the second integrated circuit devices 910 and 920 may have the same as the gate package shown in FIG. 5. Further, a first filling member 1010 may be interposed between the first and the second integrated circuit devices 910 and 920 and a second filling member 1020 may be interposed between the first and the third integrated circuit devices 910 and 930.

Thus, the metal lines of the wiring structures in the first and the third integrated circuit devices 910 and 930 may be electrically connected to the metal line of the wiring structure of the second integrated circuit device 920 through the first and the third penetration electrodes. Accordingly, the first, the second and the third integrated circuit devices 910, 920 and 930 may be assembled into the stack package 1100 functioning as a single electronic device.

In each integrated circuit device of the stack package 1100, an additional dielectric gap may be provided in each penetration electrode of the integrated circuit device. Thus, signal interferences and parasitic capacitances may be sufficiently reduced between the vertically neighboring penetration electrodes and the transient phenomena around the penetration electrode may be remarkably reduced although a large number of the integrated circuit devices may be stacked in the stack package 1100.

While the first and the third penetration electrodes may penetrate through the first and the third integrated circuit devices 910 and 930, the first and the third penetration electrodes may also extend downward in each of the integrated circuit devices 910 and 930 and may be protruded from the rear surface of the substrate. In addition, the third penetration electrode of the third integrated circuit device 930 may make direct contact with the metal line of the first integrated circuit device 910 without the medium of the third lower contact terminal and the first conductive pattern. That is, the first upper contact terminal 913 may make direct contact with the metal line of the first integrated circuit device 910 without the first conductive pattern and the third penetration electrode may make direct contact with the first upper contact terminal without the third lower contact terminal.

While the penetration electrode for die stack packages, e.g., the stack packages 1000 and 1100, in which the integrated circuit devices may be separated into pieces from the wafer and the integrated circuit devices may be individually stacked on each other, the penetration electrode may also be used for any other stack packages known to one of the ordinary skill in the art. For example, the penetration electrode around the dielectric gap may also be used for a wafer stack package in which the wafers including a plurality of the integrated circuit devices may be stacked without separation of the integrated circuit devices from the wafer.

Therefore, the signal interferences and parasitic capacitances between the penetration electrodes of the vertically stacked integrated circuit devices may be sufficiently prevented or inhibited due to the improvement of the dielectric characteristics of the penetration electrode as well as between the penetration electrodes of the same integrated circuit device in the stack package. Thus, the stack package may be stably operated with higher reliability despite the higher stack density of the integrated circuit devices.

According to the example embodiments of the present inventive concepts, an additional dielectric member may be provided around the conductive plug of the penetration electrode for the integrated circuit device, thereby improving the dielectric characteristics of the penetration electrode in the integrated circuit devices. Particularly, a gap may be formed around the conductive plug by the solid reaction of the reactants for a base layer and just merely filling up the gap with a dry air may provide the dielectric air gap around the conductive plug of the penetration electrode.

Thus, the dielectric characteristics of the penetration electrode may be easily improved. Accordingly, when the gap distance between the neighboring penetration electrodes may be reduced due to the higher integration degree of the integrated circuit device and the higher stack density of the stack package, the signal interferences and the parasitic capacitance may be sufficiently prevented or inhibited. Thus, the integration circuit device and the stack package including a plurality of the integrated circuit devices may be stably operated with higher reliability.

The foregoing is illustrative of example embodiments and is not to be construed as limiting thereof Although a few example embodiments have been described, those skilled in the art will readily appreciate that many modifications are possible in the example embodiments without materially departing from the novel teachings and advantages of the present inventive concepts. Accordingly, all such modifications are intended to be included within the scope as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. An integrated circuit device comprising:
a conductive structure on a substrate having a through hole, the conductive structure including a plurality of semiconductor chips and at least one contact structure;
a wiring structure on the conductive structure, the wiring structure including a metal line through which signals are transferred to the conductive structure; and
a penetration electrode in the through hole,
the penetration electrode including,
a conductive plug configured to electrically connect to at least one of the conductive structure and the wiring structure, and
a pair of a base layer and a gap between the conductive plug and a sidewall of the through hole such that the pair of the base layer and the gap encloses the conductive plug, the base layer including a product of a solid reaction of reactants having different diffusion speeds.

2. The integrated circuit device of claim 1, wherein the gap is filled with one of an air and a vacuum such that the conductive plug is enclosed by a dielectric air gap.

3. The integrated circuit device claim 1, wherein the base layer comprises at least one material selecting from the group consisting of BeNi, BeCo, Co₃S₄, CoSe, CoTe, ZnS, PbS, CuS, AuPt, MoS₂, AlN, CdS, ZnAl₂O₄, Zn₂SiO₄, SrTiO₃, BaTiO₃ and combinations thereof.

4. The integrated circuit device of claim 1, wherein the penetration electrode further comprises:
an insulation layer configured to electrically insulate the conductive plug from the conductive structure and the wiring structure; and
a barrier layer configured to enclose the conductive plug.

5. The integrated circuit device of claim 4, wherein the base layer is positioned on the insulation layer, and the gap is interposed between the base layer and the barrier layer.

6. The integrated circuit device of claim 4, wherein the gap is interposed between the insulation layer and the base layer, and the base layer is positioned on the barrier layer.

7. The integrated circuit device of claim 4, wherein the insulation layer, the barrier layer and the base layer are sequentially formed on the sidewall of the through hole, and the gap is interposed between the base layer and the conductive plug.

8. The integrated circuit device of claim 1, wherein the conductive plug includes at least one material selected from the group consisting of copper (Cu), nickel (Ni), tungsten (W) and combinations thereof.

9. The integrated circuit device of claim 1, wherein the penetration electrode penetrates through the conductive structure in order to make contact with a lower surface of the metal line of the wiring structure.

10. The integrated circuit device of claim 1, wherein the penetration electrode penetrates through the conductive structure and the wiring structure in order to make contact with an upper surface of the metal line of the wiring structure.

11-20. (canceled)

21. An integrated circuit device comprising:
a conductive structure on a substrate having a through hole;
a wiring structure on the conductive structure; and
a penetration electrode in the through hole, the penetration electrode including a conductive plug configured to electrically connect to at least one of the conductive structure and the wiring structure, and a dielectric gap between the conductive plug and a sidewall of the through hole such that the dielectric gap encloses the conductive plug.

22. The integrated circuit device of claim 21, wherein the conductive structure includes a plurality of semiconductor chips and at least one contact structure, and the wiring structure includes a metal line through which signals are transferred to the conductive structure.

23. The integrated circuit device of claim 21, wherein the penetration electrode further comprises:
a base layer adjacent to the dielectric gap, the base layer including a product of a solid reaction of reactants having different diffusion speeds;
an insulation layer configured to electrically insulate the conductive plug from the conductive structure and the wiring structure; and
a barrier layer configured to enclose the conductive plug.

24. The integrated circuit device claim 22, wherein the base layer comprises at least one material selecting from the group consisting of BeNi, BeCo, Co₃S₄, CoSe, CoTe, ZnS, PbS, CuS, AuPt, MoS₂, MN, CdS, ZnAl₂O₄, Zn₂SiO₄, SrTiO₃, BaTiO₃ and combinations thereof.

25. The integrated circuit device of claim 22, wherein the base layer is positioned on the insulation layer, and the dielectric gap is interposed between the base layer and the barrier layer.

26. The integrated circuit device of claim 22, wherein the dielectric gap is interposed between the insulation layer and the base layer, and the base layer is positioned on the barrier layer.

27. The integrated circuit device of claim 22, wherein the insulation layer, the barrier layer and the base layer are sequentially formed on the sidewall of the through hole, and the dielectric gap is interposed between the base layer and the conductive plug.

28. The integrated circuit device of claim 21, wherein the conductive plug includes at least one material selected from the group consisting of copper (Cu), nickel (Ni), tungsten (W) and combinations thereof.

29-31. (canceled)
